(19) United States
(12) Patent Application Publication
(10) Pub. No.: US 2008/0298153 A1
(43) Pub. Date: Dec. 4, 2008

(54) Semiconductor memory device

(75) Inventor: Kenji Mae, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/153,972

(22) Filed: May 28, 2008

(30) Foreign Application Priority Data
May 30, 2007 (JP) P2007-143144

(51) Int. Cl. G11C 7/00; G11C 8/00

(52) U.S. Cl. 365/222; 365/236; 365/230.06

(57) ABSTRACT

The present invention provides a semiconductor memory device with an open bit line structure in which sense amplifiers are arranged in a zigzag pattern and a plurality of banks, each having a plurality of mats, are provided. The semiconductor memory device includes: a refresh counter that counts the number of refresh commands and generates word line addresses; pre-decoders, each of which is provided for a corresponding bank, and which pre-decodes the word line address and outputs a pre-decode signal for selecting a mat row; bit arrangement changing circuits each of which changes the arrangement of bits of the pre-decode signal when a refresh signal indicating a refresh operation is input; and X decoders each of which outputs signals for driving a mat row and a word line according to the pre-decode signal and the word line address.

### BACKGROUND OF THE INVENTION

1. Field of the Invention

The present invention relates to a semiconductor memory device having an open bit line structure in which sense amplifiers are arranged in a zigzag pattern.

Priority is claimed on Japanese Patent Application No. 2007-143144, filed May 30, 2007, the content of which is incorporated herein by reference.

2. Description of the Related Art

DRAM (dynamic random access memory) is a kind of semiconductor memory device, DRAM includes a plurality of memory cells (memory cell array) arranged in a matrix and a plurality of sense amplifiers connected to the memory cells.

In recent years, the mainstream of DRAMs has a structure in which one sense amplifier is provided for a plurality of memory cells (2n memory cells, where n is a natural number). An open bit line structure and a folded bit line (or two intersections) structure are used as the structure in which one sense amplifier is connected to a plurality of memory cells.

As shown in FIG. 6, in the open bit line structure, one of a pair of bit lines BL1 and BL1 connected to each sense amplifier 40 is connected to a mat 31 that is provided on one side (the left side in FIG. 6) of the sense amplifier 40, and the other bit line is connected to a mat 32 that is provided on the other side (the right side in FIG. 6) of the sense amplifier. This structure is called a one-intersection structure since word lines 51 and 52 connected to memory cells of the mats intersect with only the corresponding bit lines BL1 and BL1, respectively.

In general, the open bit line DRAM shown in FIG. 6 is more preferable to reduce chip size than the folded bit line DRAM.

That is, as shown in FIG. 7, in the open bit line structure, memory cells 72 in the mats connected to word lines 51 other than the first and last word lines are alternately connected to sense amplifiers 40A and 40B that are arranged on both sides of the memory cells through the bit lines.

The open bit line DRAM in which the sense amplifiers are thus arranged in a zigzag pattern makes it possible to significantly reduce chip size.

In FIGS. 6 and 7, only one sense amplifier is connected to each bit line. However, actually, among the memory cells included in each mat (the minimum unit of a memory cell matrix), the memory cells belonging to the same row are connected to the same bit line. For example, when the memory cells are arranged in a matrix of n rows by m columns (n and m are natural numbers) in each mat, n memory cells are connected to each bit line. In this case, 2n memory cells are connected to each sense amplifier.

As shown in FIG. 8, the memory cell array of the DRAM is divided into a plurality of banks, and each of the banks includes an X decoder, a Y decoder, and a pre-decoder that generate mat selection signals for selecting one or more mats from a plurality of mats arranged in a matrix.

The term ‘mat’ means the minimum unit of a memory cell matrix in the bank, and includes a predetermined number of memory cells arranged in a matrix.

In each of the mats, one or more sense amplifiers are provided for each bit line connected to the memory cells, and a sub word driver (not shown) is connected to each mat to drives a sub word line for selecting one or more memory cells. Since the sub word driver is not directly related to the invention, a description thereof will be omitted.

As described with reference to FIG. 7, the sense amplifiers are provided at both sides of a general mat, which will be described below. That is, the sense amplifiers are arranged in a zigzag pattern between adjacent mat rows. The sense amplifier is connected to the bit lines to which the memory cells belonging to the same row are connected, among the bit lines included in two adjacent mats.

In the specification, in the following description, the mat rows positioned at both ends of each bank (the left and right ends of each bank in FIG. 7) are referred to as end mat rows, and the mats belonging to the end mat row are referred to as end mats. In addition, as shown in FIG. 8, the mat rows positioned at both ends of each bank are referred to as end mat rows each having end mats in the specification. Meanwhile, mat rows other than the end mat rows positioned at both ends of each bank are referred to as general mat rows, and mats belonging to each of the general mat rows are referred to as general mats. The sense amplifier is provided between the end mat and the general mat, but the sense amplifier is not provided on one side of the end mat opposite to the general mat.

Further, as well known, each of the memory cells of the DRAM includes a transistor and a capacitor.

Each of the memory cells stores information by storing charge in the capacitor. The charge stored in the capacitor is gradually discharged by, for example, a leakage current of the transistor. Therefore, in order to hold information stored in the memory cell, it is necessary to perform a refresh operation at a time interval at which the charge stored in the capacitor is read as information.

The refresh operation of the DRAM is performed by sequentially selecting the word lines. In this case, it is necessary to select (activate) the mat including the word line to be selected. In each bank, the selection of the mat is performed in the unit of mat rows.

Then, a word line is selected and driven in each of the mats included in the selected mat row. In the refresh operation of the DRAM, when the word lines are sequentially selected and driven, the charge stored in each of a plurality of memory cells connected to the woid line is read and amplified by a corresponding sense amplifier, and then written to the memory cell again.

In the DRAM including a plurality of banks, the refresh operation is simultaneously performed in parallel on all the banks.

Therefore, in the DRAM having a plurality of banks according to the related art, the word line addresses of the memory cells in one bank are the same as those of the memory cells in another bank.

As a result, during the refresh operation, the word lines selected from all the banks have the same word line address. That is, the word lines are disposed at the same position.

The mat rows selected during the refresh operation are disposed at the same position in all the banks.

For example, when two word lines are selected from each bank and the refresh operation is performed on double word lines during an external refresh period, the number of end mat rows activated by the refresh operation is 1.5 times larger than that of general mat rows.

That is, as described above, in the DRAM in which the sense amplifiers are arranged in a zigzag pattern, the sense amplifiers are arranged at both sides of the general mat row, but the sense amplifiers are arranged on only one side of the end mat row.

For this reason, the number of memory cells from which information can be read when the end mat rows are activated is half the number of memory cells from which information can be read when the general mat rows are activated.

Therefore, the DRAM according to the related art is configured such that the same address is assigned to two end mat rows in each bank and a pair of mat rows are accessed similar to the general mat row.

However, in the structure in which a pair of mat rows are accessed similar to the general mat row, when the end mat rows are activated, mat row selection lines for selecting the two end mat rows and the word lines in the mats are driven one by one.

Therefore, when the end mat row is accessed, the amount of driving current for driving the mat row selection lines and the word lines is larger than that when the general mat row is accessed. In particular, during the refresh operation, since the end mat rows in all the blocks are simultaneously accessed, the peak current significantly increases, as compared to a general access operation.

For example, as described above, when two mat rows are selectively activated in each bank to perform the refresh operation, 8 mat rows are generally activated. However, when the end mat rows are activated, 4 general mat rows and 8 end mat rows, that is, a total of 12 mat rows are generally activated. Therefore, as described above, the amount of driving current is 1.5 times larger than that when the refresh operation is performed on only the general mat rows.

In the structure that activates double word lines to perform the refresh operation, even when the memory capacity of a semiconductor memory device is doubled, it is necessary to maintain the refresh cycle without any change. Therefore, when the memory capacity is doubled, the refresh time is doubled. Therefore, it is necessary to improve the capability of the memory cell to hold the charge stored therein.

Meanwhile, when the memory cells have the same capability to hold the charge stored therein, it is necessary to refresh two word lines for one refresh period by driving 2n word lines in response to n refresh commands.

In order to solve the above problems, a circuit structure has been proposed in which an X decoder that selects a word line in correspondence with an input word line address is configured such that the same word line is not selected in correspondence with an input word line address (for example, see Japanese Unexamined Patent Application, First Publication No. 2004-055005). Owing to this structure, the same mat rows are not simultaneously selected from all four banks.

That is, the X decoders in the banks are configured to have different circuit structures such that, even when the same word line address is input, different mat rows are selected from the banks. In this way, the same mat rows are not simultaneously selected from all the banks. Therefore, it is possible to prevent an increase in power consumption during a refresh operation.

However, in the semiconductor device disclosed in Japanese Unexamined Patent Application Publication No. 2004-055005, it is necessary to change the design of the circuit structure of the X decoder. To this end, the word line address does not exactly correspond to the position of the mat, and the structure of a redundancy circuit for replacing a defective word line with a redundant word line becomes complicated.

### SUMMARY OF THE INVENTION

The invention has been made to solve the above problems, and an object of the invention is to provide a semiconductor memory device that does not simultaneously or continuously access end mats in each bank during a refresh operation, thereby preventing an increase in current for driving word lines.

A first aspect of the present invention is a semiconductor memory device having an open bit line structure including: a refresh counter which counts a number of refresh commands and generates wvord line addresses; pre-decoders each of which is provided on a corresponding bank including a plurality of mats, to pre-decode some bits of the word line address or an address input from the outside and to output a pre-decode signal composed of a plurality of bits that is used for selecting a mat row; bit arrangement changing circuits each of which is provided on a corresponding one of the pre-decoders to change an arrangement of bits of the pre-decode signal in response to a refresh signal indicating a refresh operation; and an X decoder which outputs signal for driving a mat row and a word line in reference to the pre-decode signal and the word line address other than the some bits or the address input from the outside.

The bit arrangement changing circuits of the first aspect of the present invention preferably change the arrangement of bits of the pre-decode signal so as to be different for each bank.

The refresh counter of the first aspect of the present invention may output any one of a plurality of bits for selecting the mat row as the least significant bit of the word line address.

A second aspect of the present invention is a semiconductor memory device having an open bit line structure, including: a refresh counter which counts a number of refresh commands and generates word line addresses; pre-decoders each of which is provided on a corresponding bank including a plurality of mats, to pre-decode some bits of the word line address or an address input from the outside and to output a pre-decode signal, which is composed of a plurality of bits for selecting a mat row; and an X decoder outputs signal for driving a mat row and a word line in reference to the pre-decode signal and the word line address other than the some bits or the address input from the outside. The refresh counter outputs any one of a plurality of bits for selecting a mat row as the least significant bit of the word line address.

A third aspect of the present invention is a refresh method of semiconductor memory device having an open bit line structure, including: a refresh counting step of counting a number of refresh commands and generating a word line address, a pre-decoding step of pre-decoding some bits of the word line address or an address input from the outside, for each bank including a plurality of mats, and outputting a pre-decode signal, which is composed of a plurality of bits, for selecting a mat row, for the each bank; and a bit arrangement changing step of changing an arrangement of bits of the pre-decode signal in response to a refresh signal indicating a refresh operation; and an X decoding step of outputting a signal for driving a mat row and a word line in reference to the pre-decode signal and the word line address other than the some bits or the address input from the outside.

A fourth aspect of the present invention is a refresh method of a semiconductor memory device having an open bit line structure, including: a refresh counting step of counting a number of refresh commands, generating a word line address, and outputting any one of a plurality of bits for selecting a mat row as the least significant bit of the word line address; a pre-decoding step of pre-decoding some bits of the word line address or an address input from the outside, for each bank including a plurality of mats and outputting a pre-decode signal, which is composed of a plurality of bits, for selecting a mat row, for the each bank; and an X decoding step of outputting signals for driving a mat row and a word line in reference to the pre-decode signal, and the word line address other than the some bits or the address input from the outside.

A fifth aspect of the present invention is a semiconductor memory device for performing a refresh operation, including: a refresh counter which generates word line addresses in response to input of a refresh command; a pre-decoder which decodes some bits of the word line address and outputs some decoded bits as a pre-decode signal; and a bit arrangement changing circuit which changes the arrangement of bits of the pre-decode signal in response to input of the refresh command.

The semiconductor memory device of the fifth aspect of the present invention preferably further includes a selector which selects the word line address or an address input from the outside and outputs the selected address to the pre-decoder. Preferably, the selector outputs the word line address to the pre-decoder based on the refresh command.

As described above, according to the above-mentioned aspects of the invention, the bit arrangement changing circuit changes the arrangement of bits of a word line address such that the same mat row is not selected from each bank during a refresh operation, thereby distributing the timing when the end mat row is selected. Therefore, the end mats are not simultaneously selected from all the banks. As a result, it is possible to prevent an increase in current for driving the word lines, and an increase in current for driving the mat row selection lines.

Further, according to the above-mentioned aspects of the invention, during a refresh operation and the other operations, the bit arrangement changing circuit can select whether to change the arrangement of bits of the word line address. According to the above-mentioned structure, it is unnecessary to change data assignment to the memory cells and the circuit structure of the X decoder unlike the related air. As a result, the structure of a redundancy circuit is not complicated.

### BRIEF DESCRIPTION OF THE DRAWINGS

FIG. 1 is a block diagram illustrating an example of the structure of a semiconductor memory device according to a first embodiment of the invention;

FIG. 2 is a conceptual diagram illustrating the structure of a bank shown in FIG. 1 that is divided from a memory cell array;

FIG. 3 is a block diagram illustrating an example of the structure of a bit arrangement changing circuit shown in FIG. 1;

FIG. 4 is a block diagram illustrating an example of the structure of a semiconductor memory device according to a second embodiment of the invention;

FIG. 5 is a block diagram illustrating an example of the structure of a refresh counter shown in FIG. 4;

FIG. 6 is a conceptual diagram illustrating an open bit line structure used in the invention;

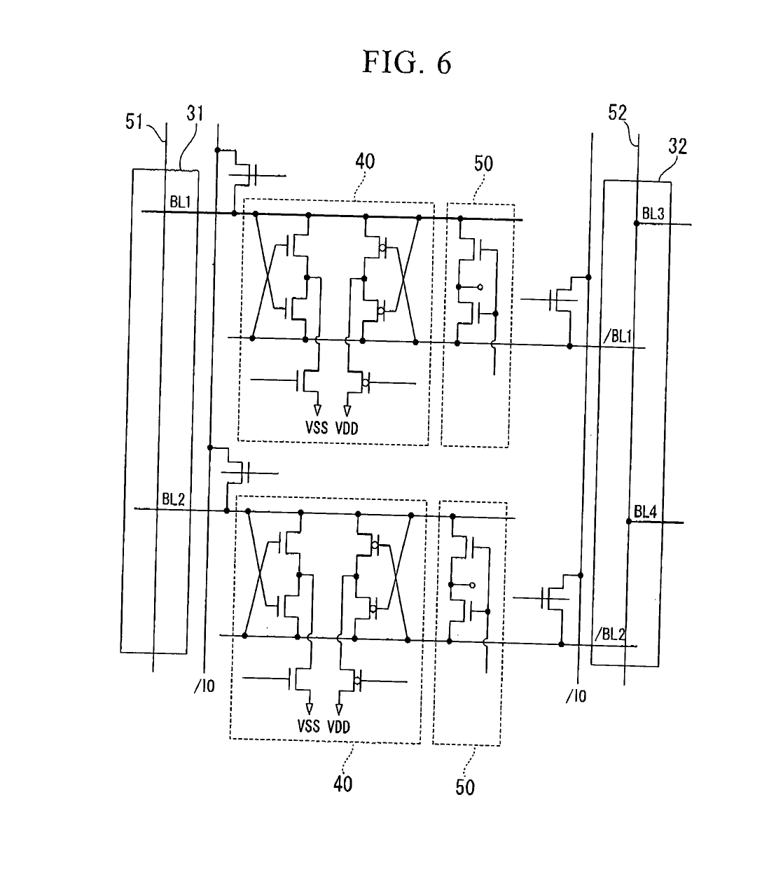

FIG. 7 is a conceptual diagram illustrating the open bit line structure used in the invention; and

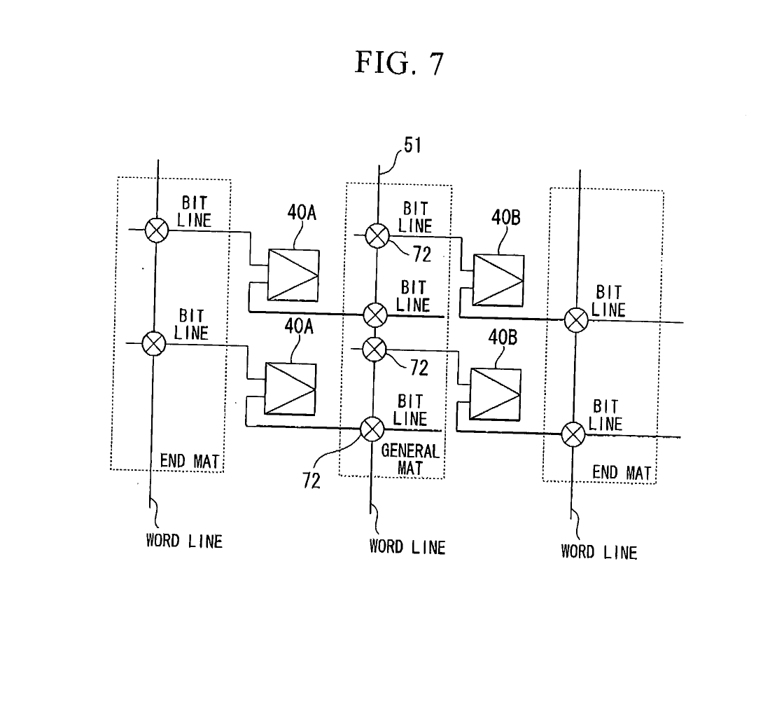

FIG. 8 is a diagram illustrating the arrangement structure of banks in a semiconductor memory device.

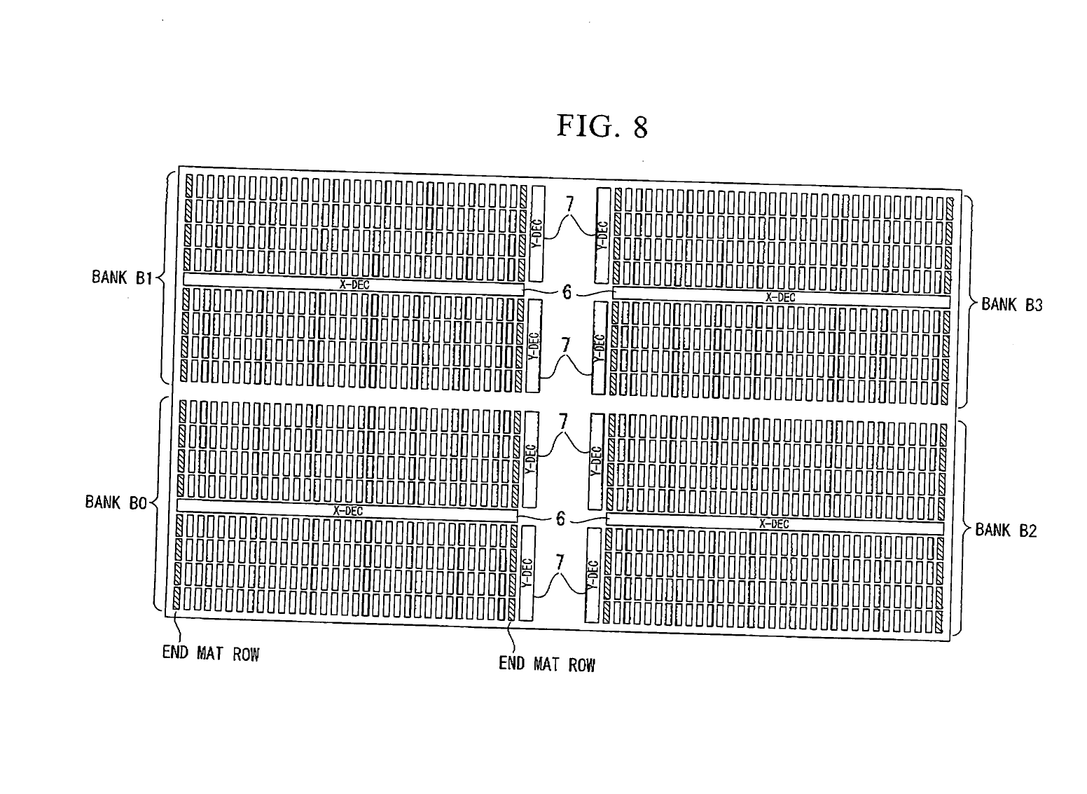

### DETAILED DESCRIPTION OF T HE INVENTION

A semiconductor device according to exemplary embodiments of the invention has the same open bit line structure as that of to the related art (i.e., mats are provided at both sides of a sense amplifier and the sense amplifier compares the potential of a bit line belonging to one mat with the potential of a bit line belonging to the other mat and amplifies the potential). The semiconductor device includes: a memory cell array that is divided into a plurality of banks each of which includes a plurality of mats arranged in a matrix, each of the mats including a plurality of memory cells arranged in a matrix; a plurality of mat row selection lines that are connected to a plurality of mat rows; and a plurality of sense amplifiers which are arranged in a zigzag pattern so as to correspond to the plurality of memory cells and each of which is arranged between adjacent mat rows.

Further, the semiconductor device includes: pre-decoders each of which is provided for a corresponding bank including a plurality of mats, and which pre-decodes some bits of a word line address generated by a refresh counter or an address input from the outside and outputs a pre-decode signal, which is composed of a plurality of bits, for selecting a mat row; and X decoders each of which outputs signals for driving a mat row and a word line according to the pre-decode signal and the word line address or the address input from the outside other than the some bits. In the embodiments of the invention, the X decoder generates signals for driving the mat row selection lines and the word lines.

### First Embodiment

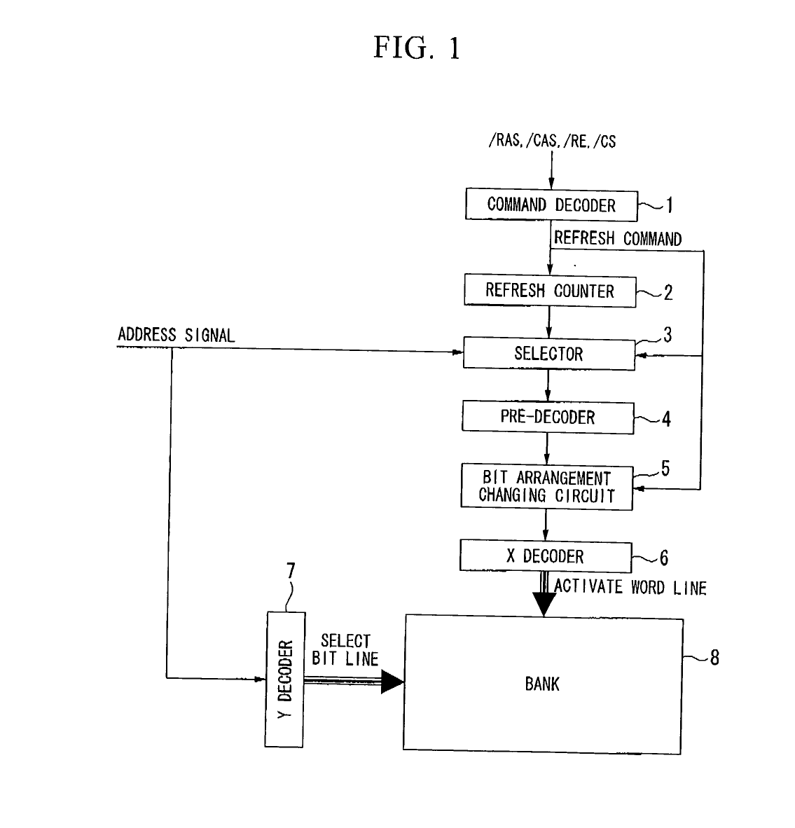

Hereinafter, a semiconductor memory device according to a first embodiment of the invention will be described with reference to the accompanying drawings. FIG. 1 is a block diagram illustrating an example of the structure of a semiconductor integrated circuit according to the first embodiment.

In FIG. 1, the semiconductor memory device according to the first embodiment of the invention includes a command decoder 1, a refresh counter 2, a selector 3, pre-decoders 4, bit arrangement changing circuits 5, X decoders 6, Y decoders 7, and a plurality of banks 8. The pre-decoder 4, the bit arrangement changing circuit 5, the X decoder 6, and the Y decoder 7 are provided for each bank.

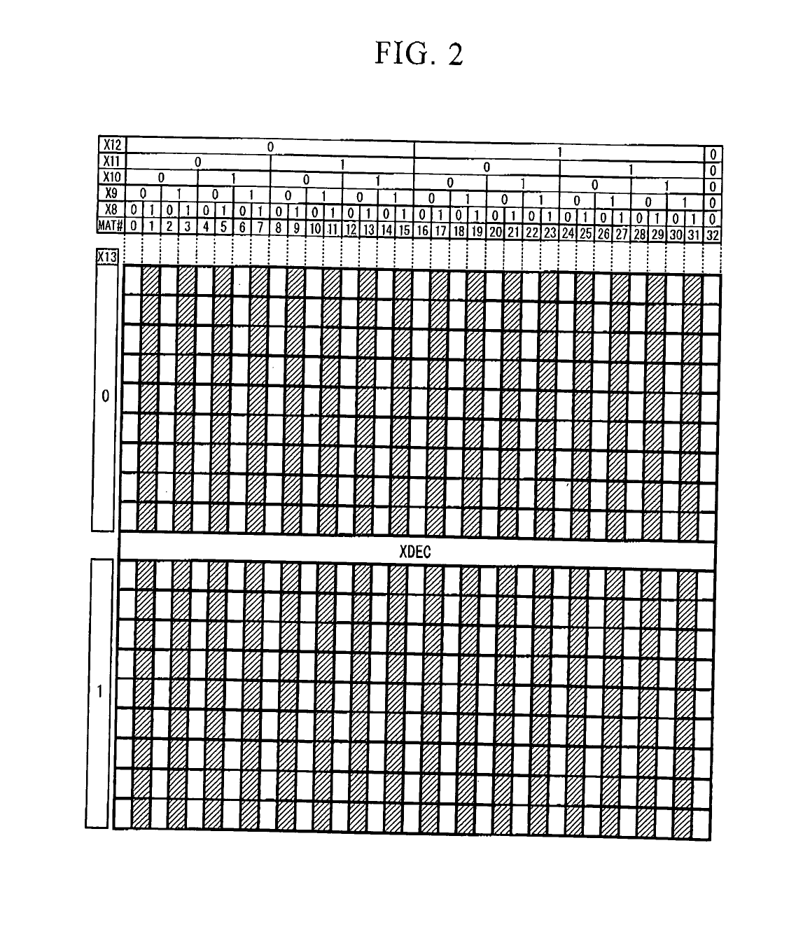

Each of the banks 8 is divided into a plurality of mats. For example, as shown in FIG. 2, the bank 8 is divided into 32 mats M0 to M31 that are set by word line addresses X8, X9, X10, X11, X12, and X13.

The mats M0 to M31 are formed by 256 normal word lines set by word line addresses X0 to X7 and a plurality of bit lines set by bit line addresses Y (Y0 to M).

The command decoder 1 generates internal control signals for controlling a refresh operation, a data read operation, and a data write operation for each of the banks 8 in response to control signals, such as /CAS (column address strobe), /RAS (row address strobe), /WE (write enable), and /CS (chip select). In the following description, the command decoder 1 generates and outputs refresh commands in response to the control signals. However, the operation of the command decoder 1 generating control signals for controlling the data write operation and the data read operation is not concerned with the invention, and thus a description thereof will be omitted.

The refresh counter 2 is a circuit that generates addresses for selecting word lines to be subjected to the refresh operation. The refresh counter 2 counts the number of times the refresh command is input, and outputs the word line addresses X0 to X11.

During the refresh operation, since the word line address X13, which is the most significant bit, is don't care, the word line address X13 is not used. Therefore, it is not necessary to generate the word line address X13 as a refresh address.

The selector 3 selects whether to use the word line addresses X0 to X13 that are input from the outside or the word line addresses X0 to X12 that are output from the refresh counter 2, on the basis of the refresh command.

For example, when no refresh command is input, the selector 3 outputs the word line addresses input from the outside to the pre-decoder 4. On the other hand, when a refresh command is input, the selector 3 outputs the word line addresses generated by the refresh counter 2 to the pre-decoder 4.

The pre-decoder 4 receives some of the word line addresses, that is, the word line addresses X8, X9, and X10 for selecting rows of mats, and outputs a signal for driving a corresponding mat row selection line as a pre-decode signal, which is composed of a plurality of bit, for selecting a row of mats. The pre-decoders 5 provided for the banks have the same structure.

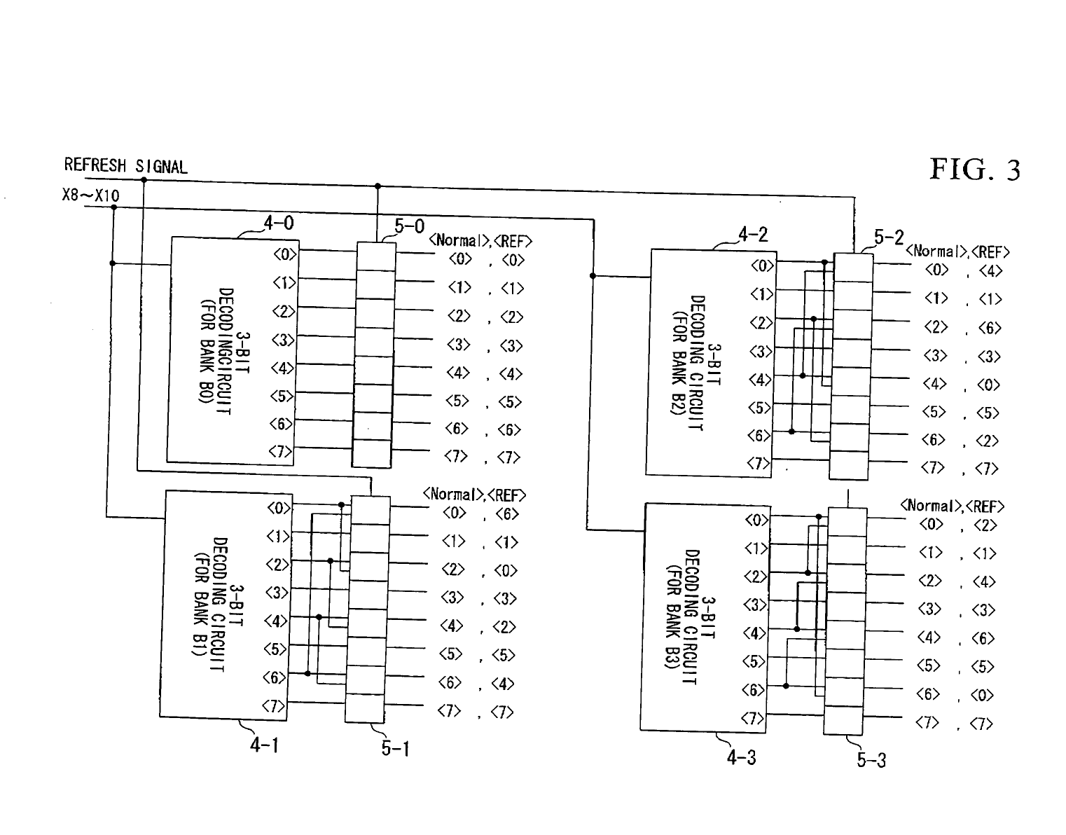

When no refresh command (refresh signal) is input, the bit arrangement changing circuit 5 outputs the input pre-decode signal without changing the bit arrangement thereof (see <Normal> in FIG. 3). Meanwhile, when a refresh command is input, the bit arrangement changing circuit 5 changes the arrangement of bits of the pre-decode signal (see <REF> in FIG. 3).

As shown in FIG. 3, in the first embodiment, since it is assumed that 4 banks are provided, the bit arrangement changing circuits 5 are configured that the arrangements of bits of the pre-decode signal among four banks are different from each other.

For example, in FIG. 3, a pre-decoder 4_0, which is a component of the pre-decoder 4, and a bit arrangement changing circuit 5_0 correspond to a bank B0, a pre-decoder 4_1 and a bit arrangement changing circuit 5_1 correspond to a bank B1, a pre-decoder 4_2 and a bit arrangement changing circuit 5_2 correspond to a bank B2, and a pre-decoder 4_3 and a bit arrangement changing circuit 5_3 correspond to a bank B3.

When word line addresses X8, X9, and X10 are input to each of the pre-decoders 4_0 to 4_3, each of the pre-decoders 4_0 to 4_3 outputs a pre-decode signal for selecting a mat row from any one bit position of the bits <B0, B1, B2, B3, B4, B5, B6, and B7>.

The arrangement of bits <B0, B1, B2, B3, B4, B5, B6, and B7> input to the bit arrangement changing circuit 5_0 is identical to the arrangement of bits <B0, B1, B2, B3, B4, B5, B6, and B7> output from the bit arrangement changing circuit 5_0. Therefore, the bit arrangement changing circuit 5_0 outputs the input pre-decode signal without any change from the same bit positions.

Meanwhile, the arrangement of bits <B0, V1, B2, B3, B4, B5, B6, and B7> input to the bit arrangement changing circuit 5_1 is different from the arrangement of bits <B6, B1, B0, B3, B2, B5, B4, and B7> output from the bit arrangement changing circuit 5_1. For example, when a bit <B0> is input, a pre-decode signal at a bit position corresponding to a bit <B2> is output.

Similarly, the arrangement of bits <B0, B1, B2, B3, B4, B5, B6, and B7> input to the bit arrangement changing circuit 5_2 is different from the arrangement of bits <B4, B1, B6, B3, B0, B5, B2, and B7> output from the bit arrangement changing circuit 5_2. For example, when a bit <B0> is input, a pre-decode signal at a bit position corresponding to a bit <B4> is output.

Further, the arrangement of bits <B0, B1, B2, B3, B4, B5, B6, and B7> input to the bit arrangement changing circuit 5_3 is different from the arrangement of bits <B2, B1, B4, B3, B6, B5, B0, and B7> output from the bit arrangement changing circuit 5_3. For example, when a bit <B0> is input, a pre-decode signal at a bit position corresponding to a bit <B6> is output.

As described above, when a refresh command is input, the bit arrangement changing circuits 5 change the arrangement of bits of an input pre-decode signal such that the bit arrangements of bits are different from each other for the banks, and output pre-decode signals for selecting different mat rows from the banks.

The X decoder 6 drives a mat row selection line for selecting a mat row according to the pre-decode signal and the word line address X11, drives the word lines in the selected mats according to the word line addresses X0 to X7, and activates the word lines corresponding to the input word line addresses.

The Y decoder 7 is a circuit that selects a bit line according to a bit line address Y other than the word line addresses X0 to X13 among the addresses input from the outside.

According to the above-mentioned structure, during a refresh operation, the bit arrangement changing circuit 5 changes the arrangement of bits of the pre-decode signal input from the pre-decoder 4 so as to be different for each bank, such that the same mat row is not selected.

In this way, even when the word line addresses for selecting end mat rows are input, the same mat row is not selected. Therefore, during the same refresh period, the end mat rows are not simultaneously selected from all the banks in the semiconductor integrated circuit.

Therefore, according to the first embodiment of the invention, it is possible to spatially distribute the mat row selection lines for selecting the end mats and the word lines for driving the end mats. Therefore, it is possible to prevent an increase in the peak values of a driving current for the mat row selection lines and a driving current for the word lines, and thus prevent a drop in voltage for driving the word line. As a result, it is possible to effectively perform the refresh operation.

However, the refresh counter 2 sequentially increases (adds) the bits of the word line addresses X0 to X12 by 1 whenever the refresh command is input.

Therefore, when the end mat in a bank is selected, the refresh process is continuously performed on the same end mat until the least significant bit of the word line address for mat selection, that is, the word line address X8 is changed.

### Second Embodiment

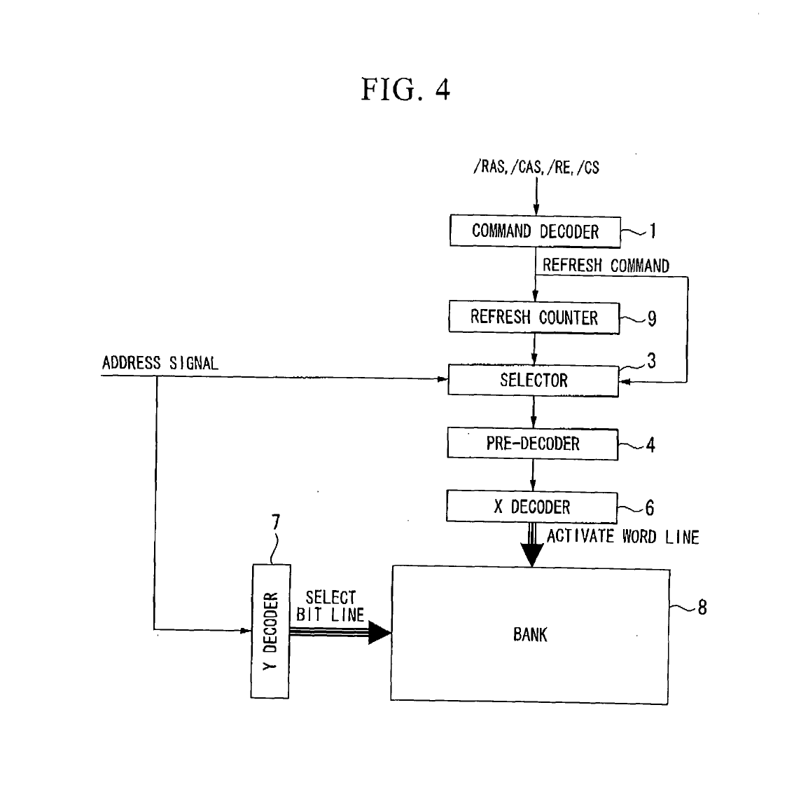

Next, the structure of a semiconductor memory device according to a second embodiment of the invention will be described with reference to FIG. 4. FIG. 4 is a block diagram illustrating an example of the structure of the semiconductor memory device according to the second embodiment.

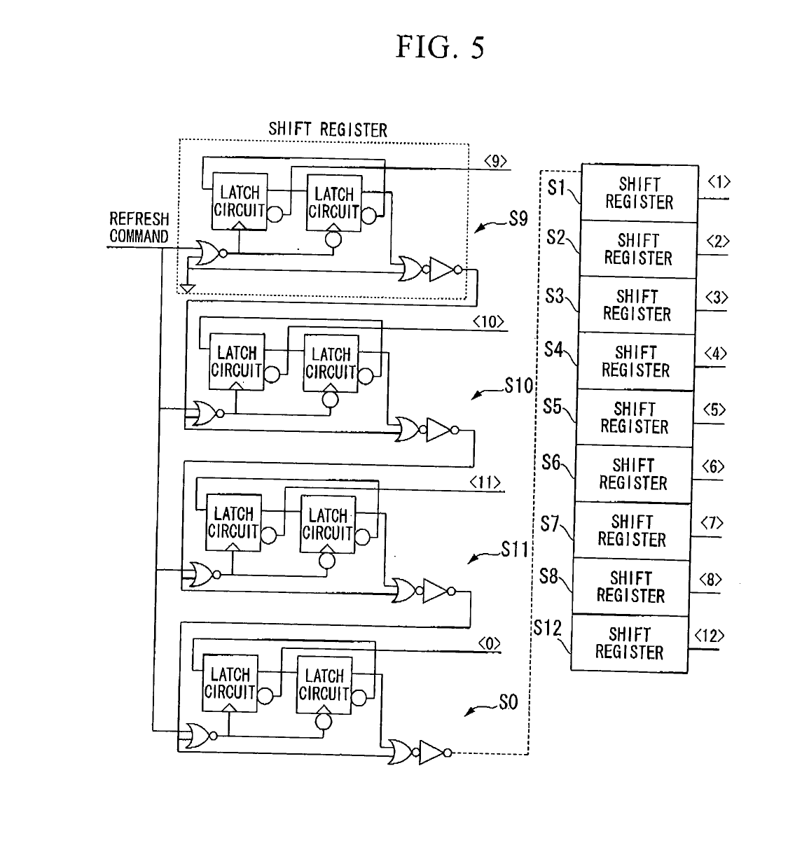

In the second embodiment, the same components as those in the first embodiment are denoted by the same reference numerals, and thus a description thereof will be omitted. The second embodiment differs from the first embodiment in that the pre-decode signal output from the pre-decoder 4 is input to the X decoder 6 without any bit change even during the refresh operation and a refresh counter 9 having the structure shown in FIG. 5 is provided.

In FIG. 5, in the structure in which double word lines are driven during each refresh period, a shift register S12 that outputs a word line address X12 is not needed, and a word line address X9 becomes the least significant bit.

As can be seen from FIG. 5, the refresh counter 9 is configured such that any one of the addresses X8 to X12 for selecting mat rows is output as the least significant bit.

In this way, when a refresh command is input, bits of the word line address for selecting a mat row are changed, and the mat row selected by each count is changed. Therefore, it is possible to prevent the same mat row from being continuously selected in each bank.

In the second embodiment, the refresh counter 9 includes shift registers S0 to S12, but the invention is not limited thereto Any count structure may be used as long as it can change the arrangement of bits of the generated word line address such that any one of a plurality of bits of the work line address for selecting a mat row is set as the least significant bit of the word line address, which is an output refresh address.

In this way, it is possible to prevent end mat rows from being continuously selected, and to temporally distribute the consumption of a driving current for the word lines.

However, since the same mat row is selected in all the banks, there is a peak of current consumption.

In the second embodiment, the addresses are assigned to the memory cells by the same method as that in the first embodiment, but the second embodiment differs from the first embodiment in the arrangement of bits of the word line address that is output as the refresh address.

### Third Embodiment

In a third embodiment, the refresh counter 2 according to the first embodiment shown in FIG. 1 is substituted for the refresh counter 9 according to the second embodiment.

According to the above-mentioned structure, similar to the first embodiment, during a refresh operation, it is possible to prevent end mats from being simultaneously selected from all the banks. In addition, similar to the second embodiment, the same mat row is not continuously selected. Therefore, it is possible to temporally and spatially distribute the mat rows to be selected. As a result, it is possible to reduce the peak current value of a driving current for driving the mat row selection lines and the word lines during the refresh operation.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor memory device having an open bit line structure, comprising:
a refresh counter which counts a number of refresh commands and generates word line addresses;
pre-decoders each of which is provided on a corresponding bank including a plurality of mats to pre-decode some bits of the word line address or an address input from the outside and to output a pre-decode signal composed of a plurality of bits that is used for selecting a mat row;
bit arrangement changing circuits each of which is provided on corresponding one of the pre-decoders to change an arrangement of bits of the pre-decode signal in response to a refresh signal indicating a refresh operation; and
an X decoder which outputs signal for driving a mat row and a word line in response to the pre-decode signal and the word line address other than the some bits or the address input from the outside.

2. The semiconductor memory device according to claim 1,
wherein the bit arrangement changing circuits change the arrangement of bits of the pre-decode signal so as to be different for each bank.

3. The semiconductor memory device according to claim 1,
wherein the refresh counter output any one of a plurality of bits for selecting the mat row as the least significant bit of the word line address.

4. A semiconductor memory device having an open bit line structure, comprising:
a refresh counter which counts a number of refresh commands and generates word line addresses;
pre-decoders each of which is provided on a corresponding bank including a plurality of mats to pre-decode some bits of the word line address or an address input from the outside and to output a pre-decode signal, which is composed of a plurality of bits for selecting a mat row; and
An X decoder which outputs signal for driving a mat row and a word line in reference to the pre-decode signal and the word line address other than the some bits or the address input from the outside,
wherein the refresh counter outputs any one of a plurality of bits for selecting a mat row as the least significant bit of the word line address.

5. A refresh method of a semiconductor memory device having an open bit line structure, comprising:
a refresh counting step of counting a number of refresh commands and generating word line addresses;
a pre-decoding step of pre-decoding some bits of the word line address or an address input from the outside, for each bank including a plurality of mats, and outputting a pre-decode signal, which is composed of a plurality of bits, for selecting a mat row, for the each bank;
a bit arrangement changing step of changing an arrangement of bits of the pre-decode signal in response to a refresh signal indicating a refresh operation; and
an X decoding step of outputting a signal for driving a mat row and a word line in reference to the pre-decode signal and the word line address other than the some bits or the address input from the outside.

6. A refresh method of a semiconductor memory device having an open bit line structure, comprising:
a refresh counting step of counting a number of refresh commands, generating word line addresses, and outputting any one of a plurality of bits for selecting a mat row as the least significant bit of the word line address;
a pre-decoding step of pre-decoding some bits of the word line address or an address input from the outside, for each bank including a plurality of mats, outputting a pre-decode signal, which is composed of a plurality of bits, for selecting a mat row, for the each bank; and
an X decoding step of outputting signals for driving a mat row and a word line in reference to the pre-decode signal and the word line address other than the some bits or the address input from the outside.

7. A semiconductor memory device performing a refresh operation, comprising:
a refresh counter which generates word line addresses in response to input of a refresh command;
a pre-decoder which decodes some bits of the word line address and outputs some decoded bits as a pre-decode signal; and
a bit arrangement changing circuit which changes the arrangement of bits of the pre-decode signal in response to input of the refresh command.

8. The semiconductor memory device according to claim 7, further comprising:
a selector which selects the word line address or an address input from the outside and outputs the selected address to the pre-decoder,
wherein the selector outputs the word line address to the pre-decoder based on the refresh command.
